(19) United States
(12) Patent Application Publication
(10) Pub. No.: US 2025/0133799 A1
(43) Pub. Date: Apr. 24, 2025

(54) INNER SPACER HAVING A CURVED PORTION

(71) Applicant: International Business Machines Corporation, Armonk, NY (US)

(72) Inventors: Susan Ng Emans, Albany, NY (US); Julien Frougier, Albany, NY (US); Ruilong Xie, Niskayuna, NY (US); Min Gyu Sung, Latham, NY (US); Juntao Li, Cohoes, NY (US); Chanro Park, Clifton Park, NY (US)

(21) Appl. No.: 18/490,867

(22) Filed: Oct. 20, 2023

(51) Int. Cl. H01L 29/66; H01L 29/06; H01L 29/775; H01L 29/786

(52) U.S. Cl. CPC H10D 64/018; H10D 30/014; H10D 30/031; H10D 30/43; H10D 30/6757; H10D 62/116

(57) ABSTRACT

Embodiments of the invention include a semiconductor structure having nanosheets separated by inner spacers, the inner spacers having a curved portion in a dimension. The semiconductor structure includes source/drain regions formed adjacent to the nanosheets and gate material formed on the nanosheets.

### BACKGROUND

The present invention generally relates to fabrication methods and resulting structures for integrated circuits (ICs), and more specifically, to fabrication methods and resulting structures configured and arranged for providing a gate-all-around device with an improved spacer profile for robust gate-to-source/drain isolation.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer, on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing a gate-all-around device with an improved spacer profile for robust gate-to-source/drain isolation. A non-limiting method of forming a semiconductor structure includes providing nanosheets separated by inner spacers, the inner spacers having a curved portion in a dimension. The method includes forming source/drain regions adjacent to the nanosheets and forming gate material formed on the nanosheets.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and cross-sectional view of a portion of an integrated circuit (IC) under-fabrication after fabrication operations according to one or more embodiments of the invention;

FIGS. 2A and 2B respectively depict a top view and a cross-sectional view of a portion of an IC under-fabrication after fabrication operations according to one or more embodiments of the invention;

FIGS. 3A and 3B respectively depict a top view and a cross-sectional view of a portion of an IC under-fabrication after fabrication operations according to one or more embodiments of the invention;

FIGS. 4A and 4B respectively depict a top view and a cross-sectional view of a portion of an IC under-fabrication after fabrication operations according to one or more embodiments of the invention;

FIGS. 5A and 5B respectively depict a top view and a cross-sectional view of a portion of an IC under-fabrication after fabrication operations according to one or more embodiments of the invention;

FIGS. 6A, 6B, 6C, and 6D respectively depict a top view and cross-sectional views of a portion of an IC under-fabrication after fabrication operations according to one or more embodiments of the invention;

FIGS. 7A, 7B, 7C, and 7D respectively depict a top view and cross-sectional views of a portion of an IC under-fabrication after fabrication operations according to one or more embodiments of the invention;

FIGS. 8A, 8B, 8C, and 8D respectively depict a top view and cross-sectional views of a portion of an IC under-fabrication after fabrication operations according to one or more embodiments of the invention;

FIGS. 9A, 9B, 9C, and 9D respectively depict a top view and cross-sectional views of a portion of an IC under-fabrication after fabrication operations according to one or more embodiments of the invention;

FIGS. 10A, 10B, 10C, and 10D respectively depict a top view and cross-sectional views of a portion of an IC under-fabrication after fabrication operations according to one or more embodiments of the invention;

FIGS. 11A, 11B, 11C, and 11D respectively depict a top view and cross-sectional views of a portion of an IC under-fabrication after fabrication operations according to one or more embodiments of the invention;

FIGS. 12A and 12B respectively depict a top view and cross-sectional view of a portion of an IC under-fabrication after fabrication operations according to one or more embodiments of the invention;

FIGS. 13A and 13B respectively depict a top view and cross-sectional view of a portion of an IC under-fabrication after fabrication operations according to one or more embodiments of the invention;

FIGS. 14A and 14B respectively depict a top view and cross-sectional view of a portion of an IC under-fabrication after fabrication operations according to one or more embodiments of the invention;

FIGS. 15A and 15B respectively depict a top view and cross-sectional view of a portion of an IC under-fabrication after fabrication operations according to one or more embodiments of the invention;

FIGS. 16A, 16B, 16C, 16D, and 16E respectively depict a top view and cross-sectional views of a portion of an IC under-fabrication after fabrication operations according to one or more embodiments of the invention;

FIGS. 17A, 17B, 17C, 17D, and 17E respectively depict a top view and cross-sectional views of a portion of an IC under-fabrication after fabrication operations according to one or more embodiments of the invention;

FIGS. 18A, 18B, 18C, 18D, and 18E respectively depict a top view and cross-sectional views of a portion of an IC under-fabrication after fabrication operations according to one or more embodiments of the invention;

FIGS. 19A, 19B, 19C, 19D, and 19E respectively depict a top view and cross-sectional views of a portion of an IC under-fabrication after fabrication operations according to one or more embodiments of the invention;

FIGS. 20A, 20B, 20C, 20D, and 20E respectively depict a top view and cross-sectional views of a portion of an IC under-fabrication after fabrication operations according to one or more embodiments of the invention;

FIGS. 21A, 21B, 21C, 21D, and 21E respectively depict a top view and cross-sectional views of a portion of an IC under-fabrication after fabrication operations according to one or more embodiments of the invention;

FIGS. 22A and 22B respectively depict a top view and cross-sectional view of a portion of an IC under-fabrication after fabrication operations according to one or more embodiments of the invention; and

FIGS. 23A, 23B, 23C, 23D, and 23E respectively depict a top view and cross-sectional views of a portion of an IC under-fabrication after fabrication operations according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

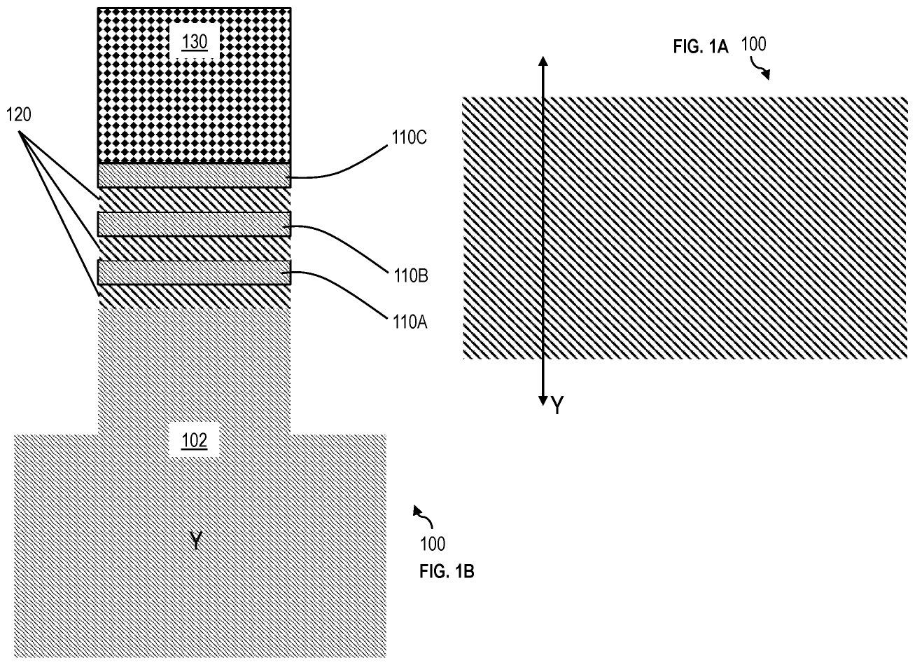

Turning now to a more detailed description of aspects of the present invention, FIG. 1A depicts a top view of a simplified illustration of a portion of an integrated circuit (IC) 100 and FIG. 1B depicts a cross-sectional view taken along Y of the IC 100. For ease of understanding, some layers may be omitted from the various top views so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

FIGS. 1A and 1B depict the IC 100 having a wafer where several fabrication processes have been performed. FIGS. 1A and 1B illustrate the IC after nanosheet stack growth and nanosheet patterning. A nanosheet stack is formed on a substrate 102. The wafer or substrate 102 may be formed of (pure) silicon. Other suitable materials can be utilized for the substrate 102. As seen in FIG. 1B, a nanosheet stack of semiconductor layers 110A, 110B, and 110C is formed with sacrificial layers 120 formed in between. The semiconductor layers 110A, 110B, and 110C can generally be referred to as semiconductor layers 110 and may include substantially pure silicon. The semiconductor layers 110 will become the channel regions for the nanosheet FET device. The semiconductor layers 110 are nanosheets. Nanosheets can have a thickness of, for example, 5 nanometers. The thickness of a nanosheet can range from about 2-10 nm, and other ranges are possible. The sacrificial layers 120 are formed of silicon germanium (SiGe), where germanium has an atomic percent (%) of about 25% and silicon is the remainder. In one or more embodiments, the atomic percent of germanium can range from about 15-30% while silicon is the remainder in the sacrificial layer 120.

A hard mask layer 130 is formed on top of the semiconductor layer 110. The hard mask layer 130 is patterned, and the patterned hard mask layer 130 is utilized to etch the semiconductor layers 110, sacrificial layers 120, and a portion of the substrate 102. A wet etch or dry etch may be utilized. Example materials of the hard mask layer 130 can include nitride materials such as silicon nitride.

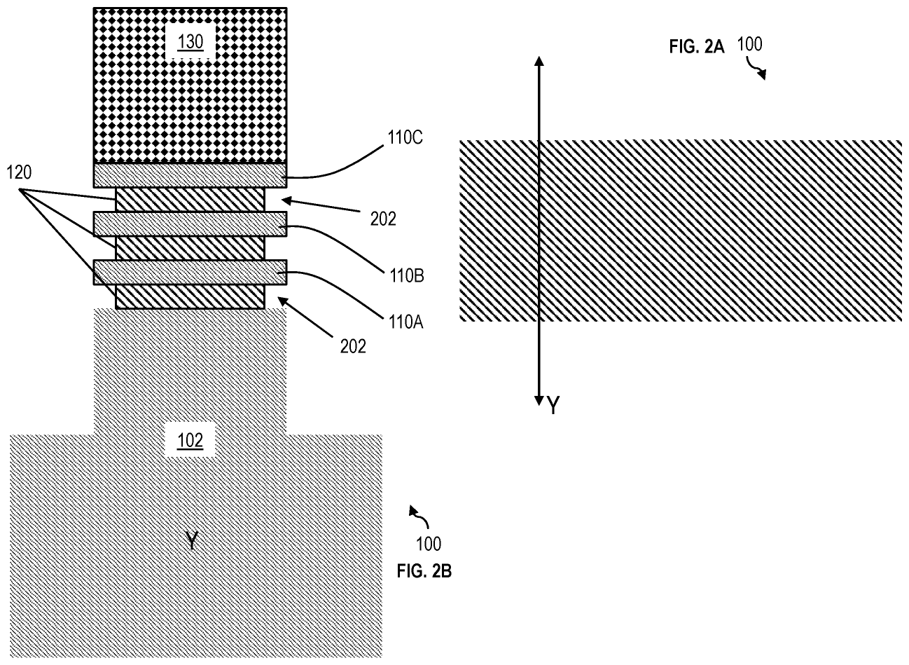

FIGS. 2A and 2B depict the IC 100 after selective indentation of the sacrificial layers 120. Reactive ion etching (RIE) may be utilized to etch the ends of the sacrificial layers 120, resulting indentations 202 at the ends of the sacrificial layers 120.

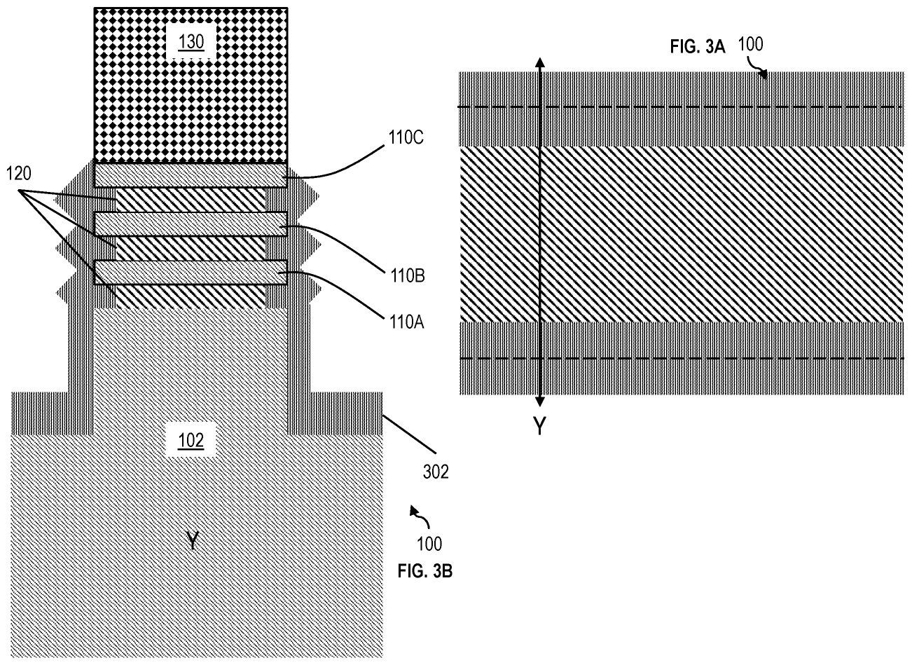

FIGS. 3A and 3B depict the IC 100 after growth of a high germanium percentage layer. A sacrificial layer 302 is deposited on the IC 100. The sacrificial layer 302 has a higher percentage of germanium than the sacrificial layer 120. The sacrificial layer 302 is formed of silicon germanium (SiGe), where germanium has an atomic percent (%) of about 35% and silicon is the remainder. In one or more embodiments, the atomic percent of germanium can range from about 35-60% while silicon is the remainder in the sacrificial layer 302.

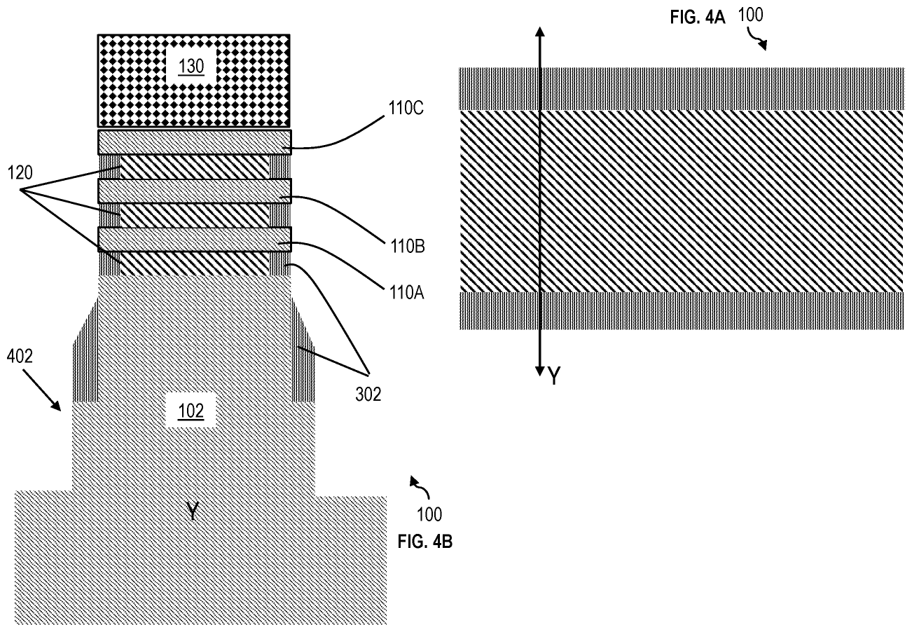

FIGS. 4A and 4B depict the IC 100 after additional directional RIE on the nanosheet stack. An isotropic etch, such as an RIE etch, is performed to etch back some of the sacrificial layer 302, resulting in stair-shaped portions 402 of the substrate 102. The material of sacrificial layer 302 sitting on part of the stairs of the stair-shaped portions 402 is carried forward to the final device.

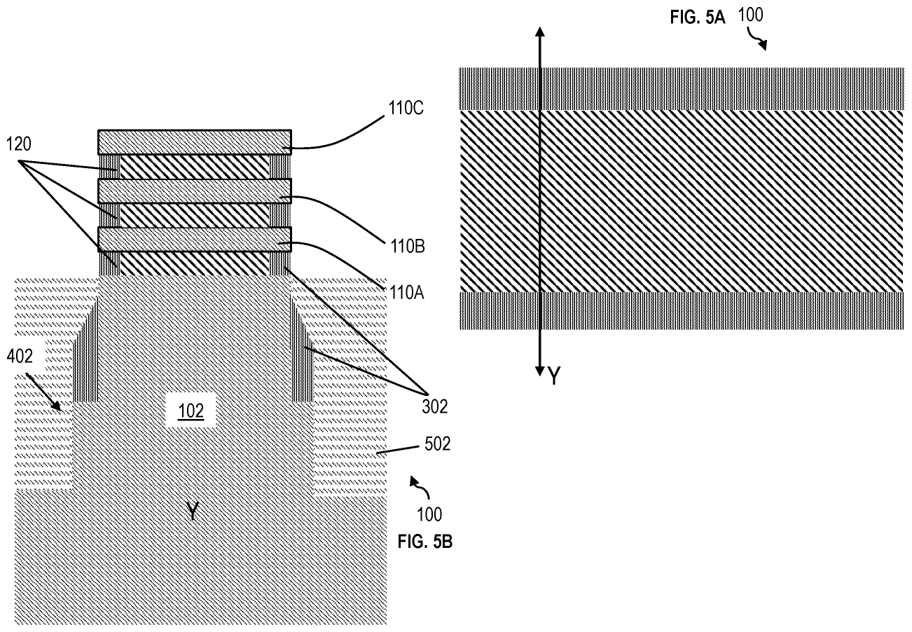

FIGS. 5A and 5B depict the IC 100 after shallow trench isolation formation, fin reveal, and hard mask removal. Material for the shallow trench isolation (STI) regions 502 is deposited. Etching is performed to etch back the material of the STI regions 502, thereby revealing the fin. The STI regions 502 encapsulate the sacrificial layer 302 that sits on the stair-shaped portions 402. The hard mask layer 130 is removed using any suitable technique, including, for example, etching, chemical mechanical polishing/planarization, etc.

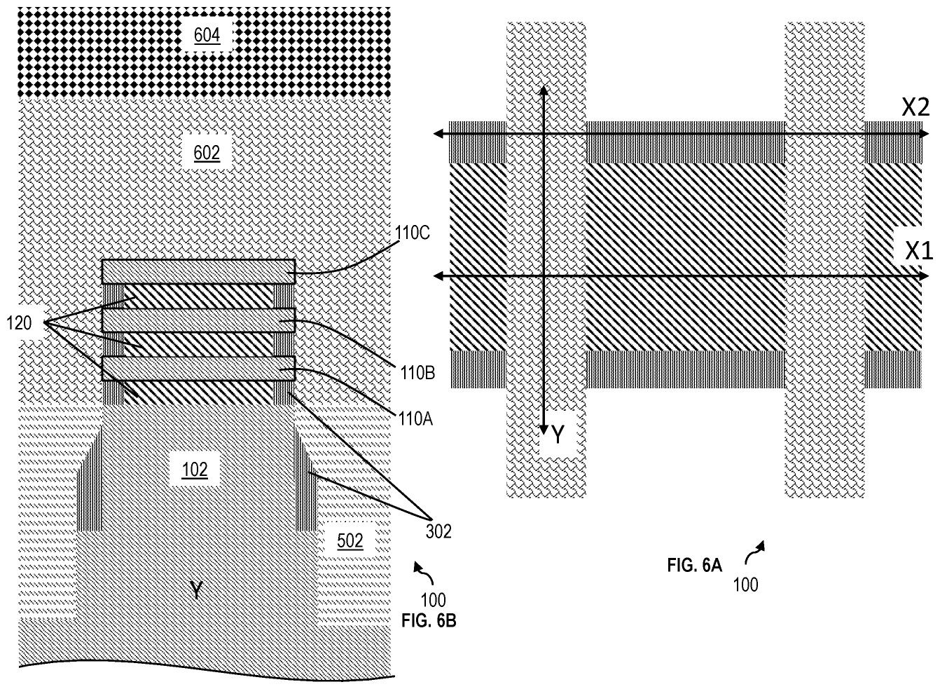

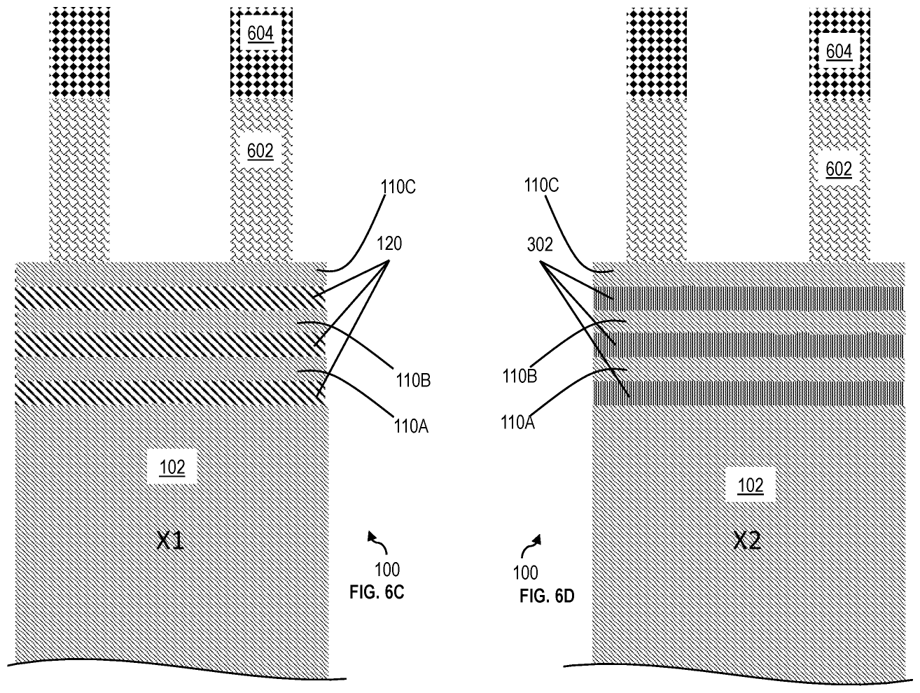

FIGS. 6A, 6B, 6C, and 6D depict the IC 100 after dummy gate formation and patterning. FIG. 6A is a top view of a simplified illustration of a portion of the IC 100, and FIG. 6B depicts a cross-sectional view taken along Y of the IC 100. FIG. 6C depicts a cross-sectional view taken along X1 of the IC 100, and FIG. 6D depicts a cross-sectional view taken along X2 of the IC 100. The fabrication of FIGS. 6A, 6B, 6C, and 6D continues from FIGS. 5A and 5B. Sacrificial gate material is formed on the IC 100 to be a dummy gate 602, and a hard mask layer 604 is formed on top of the sacrificial gate material. The hard mask layer 604 is patterned, and the patterned hard mask layer 604 is utilized to etch the sacrificial gate material into the dummy gate 602. Example materials of the dummy gate 602 can include amorphous silicon, polycrystalline silicon, etc. Example materials of the hard mask layer 604 can include nitride materials such as silicon nitride.

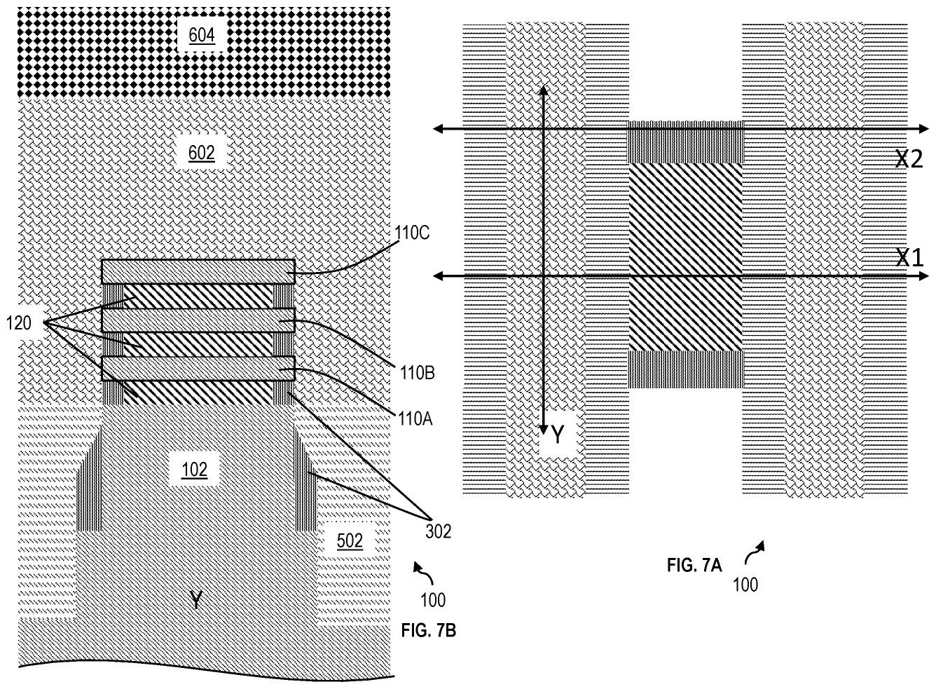

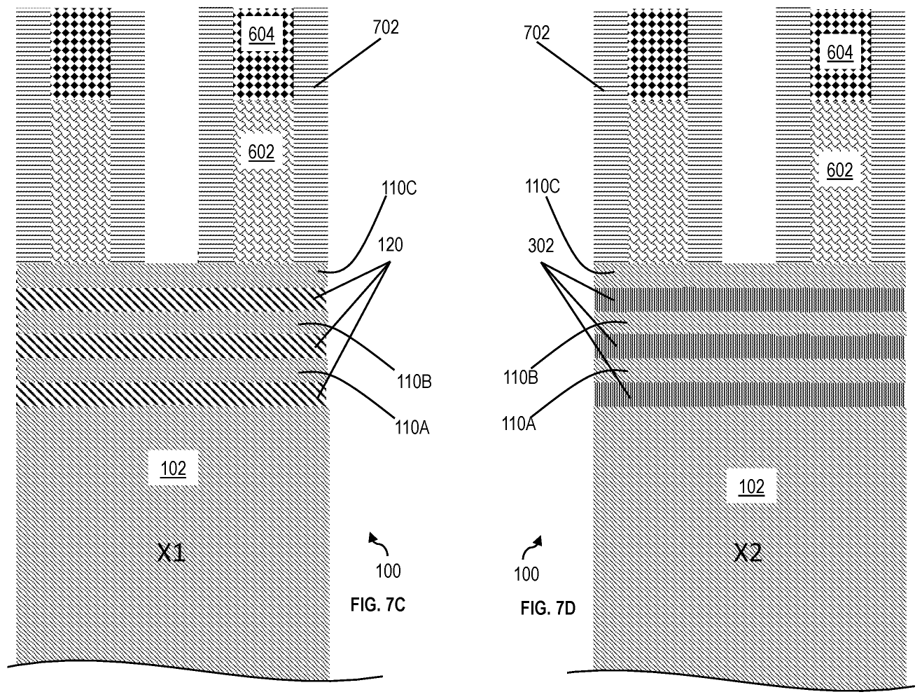

FIGS. 7A, 7B, 7C, and 7D depict the IC 100 after gate spacer deposition and etching. Gate spacer material is deposited and etched to form gate spacers 702. Example materials of the gate spacer 702 can include nitride materials, such as SiN, SiBCN, SiOCN, SiOC, etc.

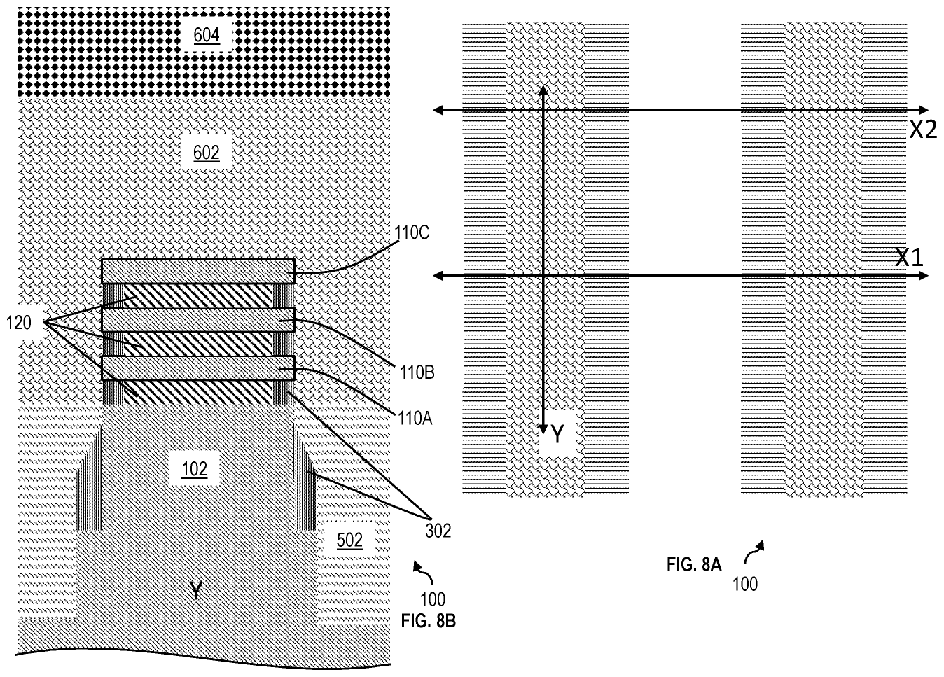

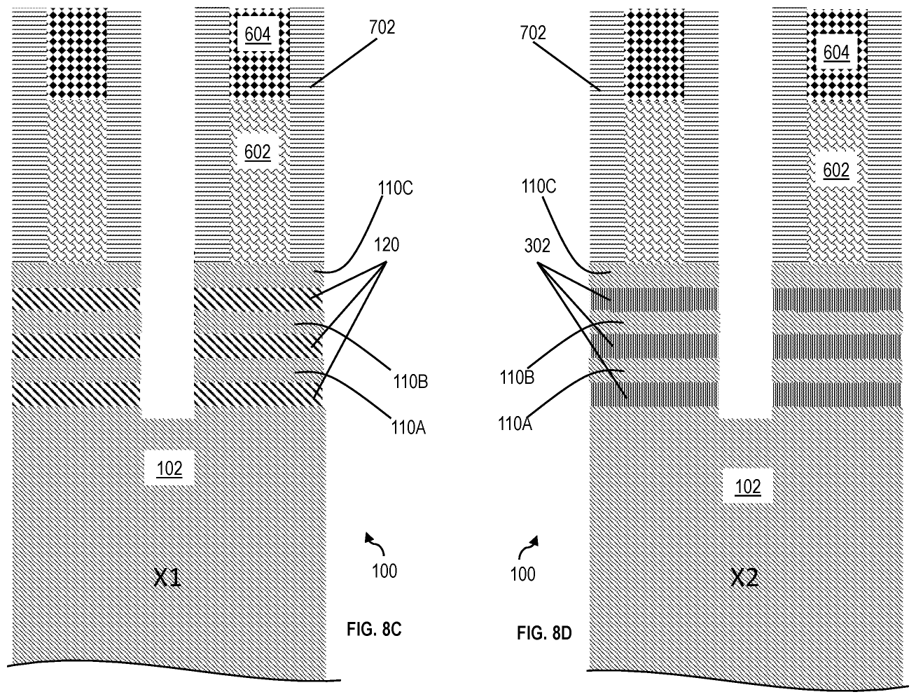

FIGS. 8A, 8B, 8C, and 8D depict the IC 100 after fin recess. Directional etching is performed while using the hard mask layer 604 and the gate spacers 702 as a protective mask, in order to trim the nanosheet stack. As a result of the etching, the unprotected portions of the semiconductor layers 110 and the sacrificial layers 120 are removed. Etching continues into a portion of the substrate 102.

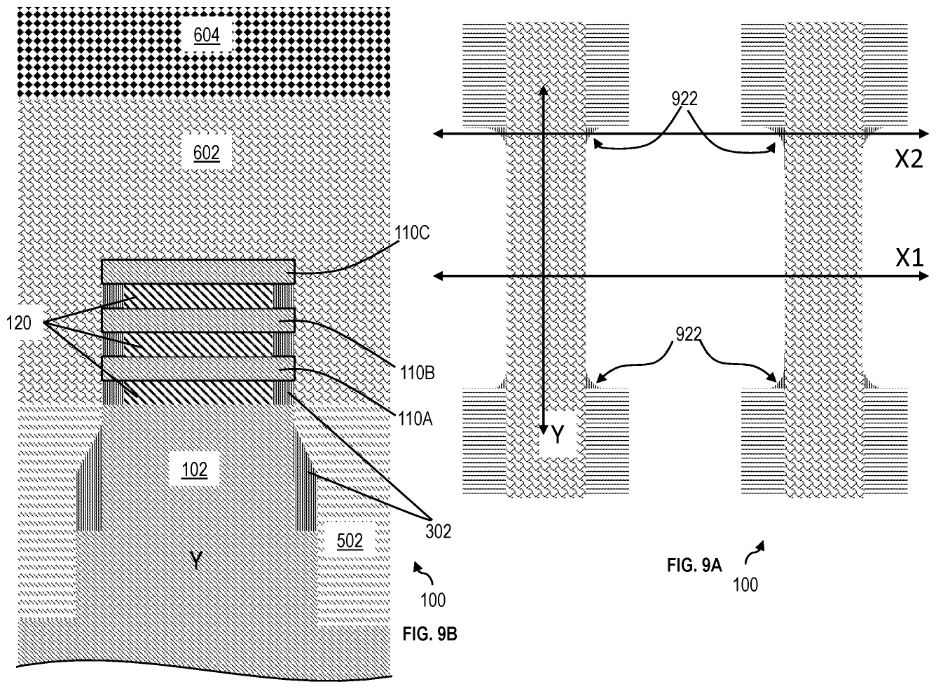

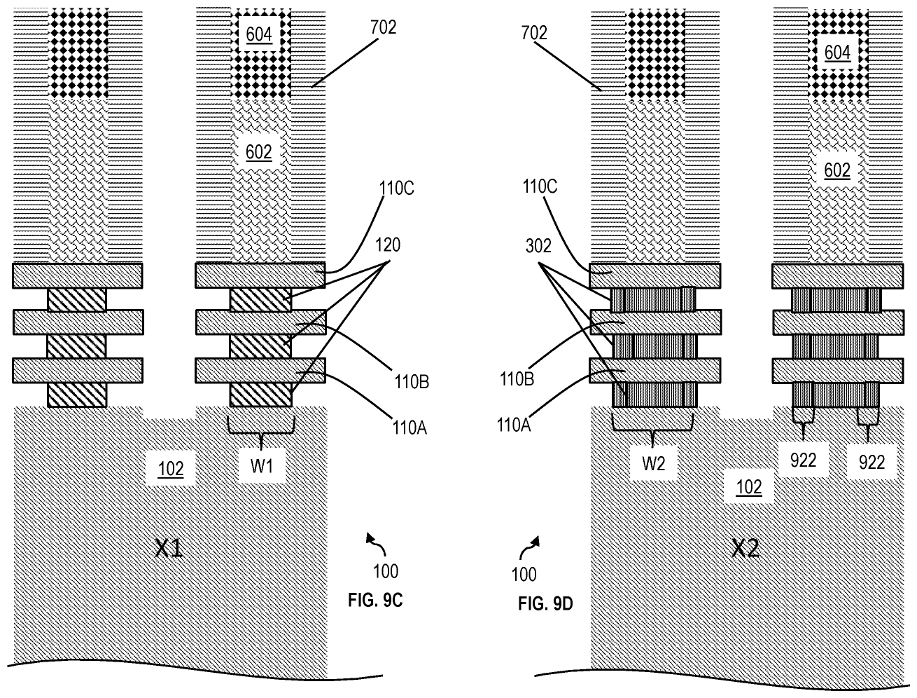

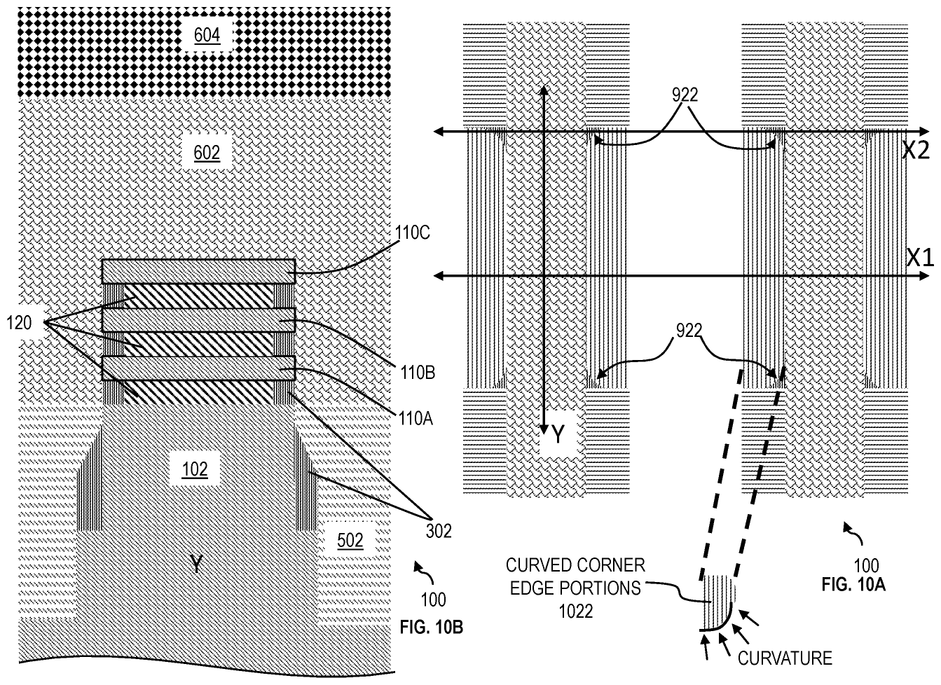

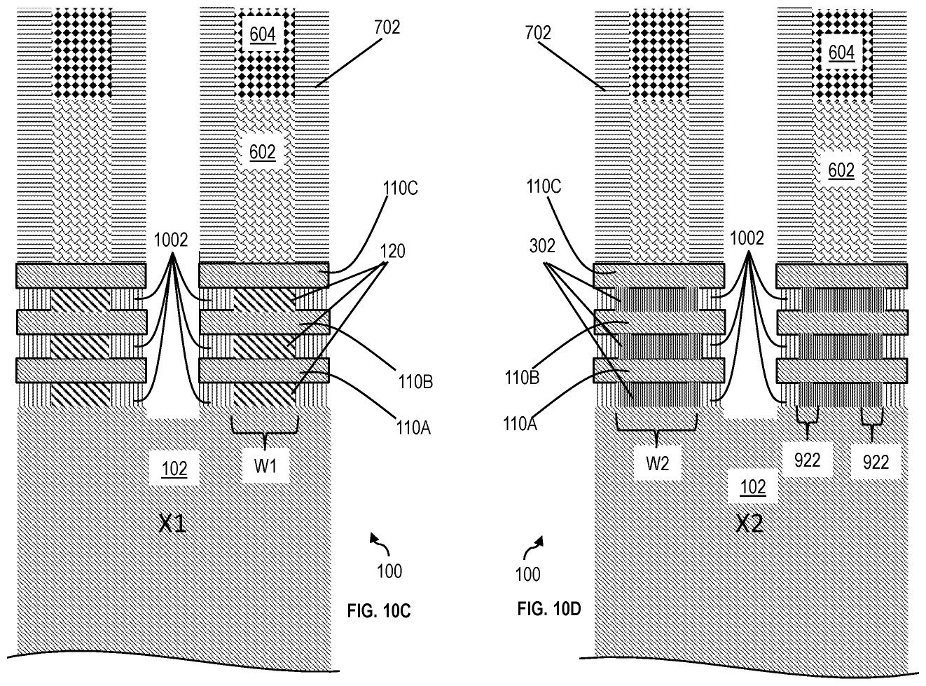

FIGS. 9A, 9B, 9C, and 9D depict the IC 100 after inner spacer indentation. In preparation to form inner spacers 1002 (depicted in FIGS. 10A, 10B, 10C, and 10D), isotropic etching is performed to selectively remove end portions of the sacrificial layers 120 and 302 resulting in cavities at the ends. Etching is performed that results in a width W1 for the sacrificial layers 120 in the x-axis as depicted in FIG. 9C and a width W2 for sacrificial layers 302 in the x-axis as depicted in FIG. 9D. The width W2 is greater than the width W1. The width W2 of sacrificial layers 302 includes additional corner edge portions 922. The higher germanium percentage in the SiGe material of the sacrificial layers 302 as compared to the lower germanium percentage in the SiGe material of the sacrificial layers 120 causes the sacrificial layers 302 to have a faster etch rate than the sacrificial layer 120. Consequently, the faster etch rate causes the formation of a spacer corner edge depicted as corner edge portions 922 that have a curvature as depicted in FIG. 9A. The curvature of the corner edge portions 922 of the sacrificial layers 302 results in an improved inner spacer profile in the y-axis. As noted herein, one or more upper layers may not be illustrated in the top view in order to avoid obscuring the figure and to highlight certain aspects for the reader, in accordance with one or more embodiments.

FIGS. 10A, 10B, 10C, and 10D depict the IC 100 after inner spacer formation. Inner spacer material is deposited to fill the cavities, and etching is performed to remove the excess spacer material, resulting in the inner spacers 1002 on the ends of the sacrificial layers 120 and 302. Also, the inner spacers 1002 are deposited to conform to a shape complementary to the curvature of the curved corner edge portions 922 of the sacrificial layers 302, thereby resulting in curved spacer corner edge portions 1022 of the inner spacers 1002 as best seen in FIGS. 10A and 10D. In FIG. 10D, the curved corner edge portions 922 of the sacrificial layers 302 cause a greater width W2 for the sacrificial layer 302, thereby resulting in the curved spacer corner edge portions 1022 of the inner spacers 1002. In one or more embodiments, the inner spacer corner rounding size can be less than 1 nanometer (nm) but greater than 0 nm for the curved spacer corner edge portions 1022 of the inner spacers 1002. In one or more embodiments, the inner spacer corner rounding size can be about 0.5-2 nm for the curved spacer corner edge portions 1022 of the inner spacers 1002. Example materials of the inner spacers 1002 can include nitrides, low-k dielectric materials, etc. Example materials of the inner spacers 1002 may include SiBCN, SiOCN, SiN, SiOC, SiC, etc.

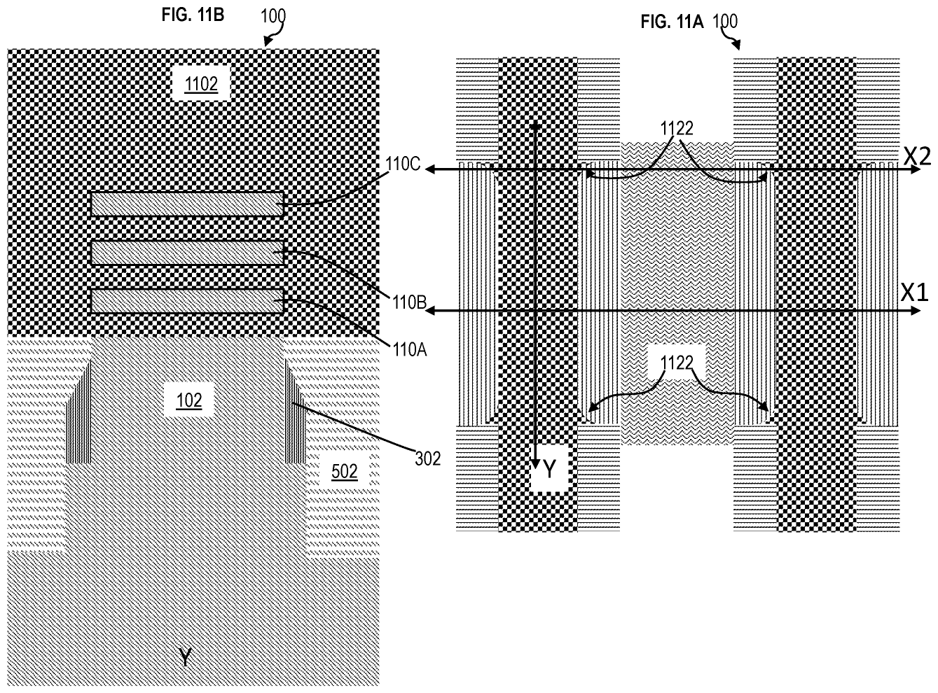

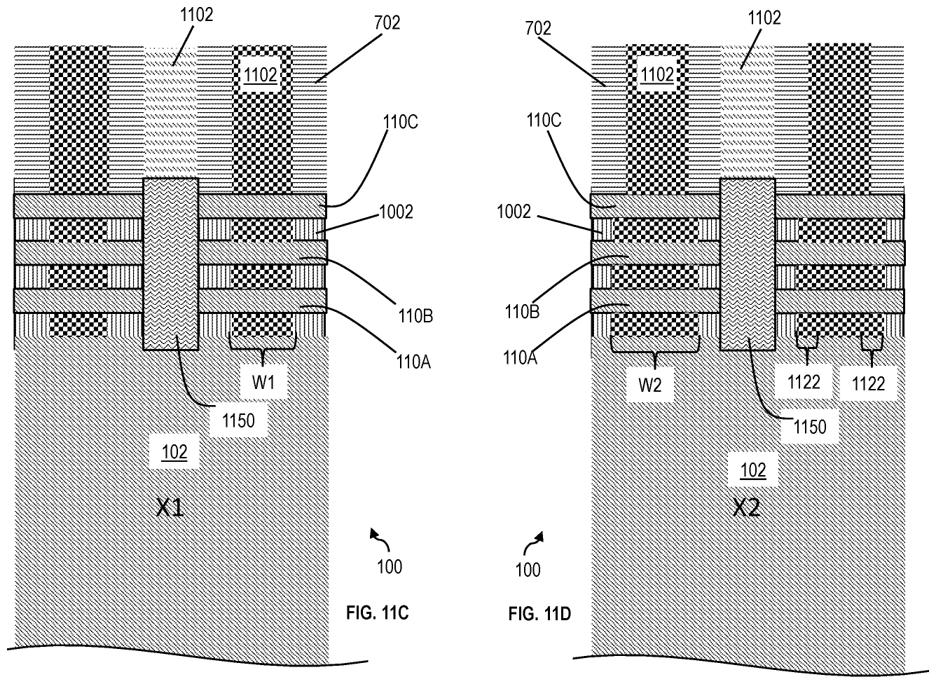

FIGS. 11A, 11B, 11C, and 11D depict the IC 100 after source and drain epitaxial deposition, interlayer/intralayer dielectric formation, and replacement gate (RMG) formation. To form epitaxial source/drain regions 1150, semiconductor material is deposited and epitaxially grown from the nanosheet semiconductor layers 110 and the substrate 102. The deposited semiconductor material can be doped with n-type or p-type dopants according to whether an n-type or p-type transistor is being formed.

For dummy gate removal, etching is performed to remove the hard mask layer 604 and further etching is performed to remove the dummy gate 602. In one or more embodiments, a mask can be utilized during the etching to protect portions of the IC 100. The removal of the hard mask layer 604 and dummy gate 602 results in trenches exposing the top-most semiconductor layers 110C.

As part of the channel release, etching is performed to selectively remove the sacrificial layers 120 and 302. The etching results in the nanosheet semiconductor layers 110 being exposed and available for deposition of gate material 1102. The gate material 1102 is deposited on the IC 100. The gate material 1102 includes gate corner edge portions 1122 that have a curvature complementary and abutting the curvature of the spacer corner edge portion 1022 of the inner spacers 1002. The gate corner edge portions 1122 of the gate material 1102 is formed to replace and formed with the same shape as the curved corner edge portions 922 of the sacrificial layers 302. Similarly, the curved corner edge portions 922 of the sacrificial layers 302 in FIG. 9 result in the formation of the curved spacer corner edge portions 1022 of the inner spacers 1002 in FIG. 10.

As seen in FIG. 11B, the material of the sacrificial layer 302 on the stair-shaped portions 402 of the substrate 102 (depicted in FIG. 4B) remains as sidewall spacers of silicon germanium material on the stair-shaped portions 402.

The gate material 1102 includes high-k material deposition and work function material deposition. Gate material 1102 is formed around the semiconductor layers 110. The gate material 1102 includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown, contact formation and ILD formation are performed. ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions 1150.

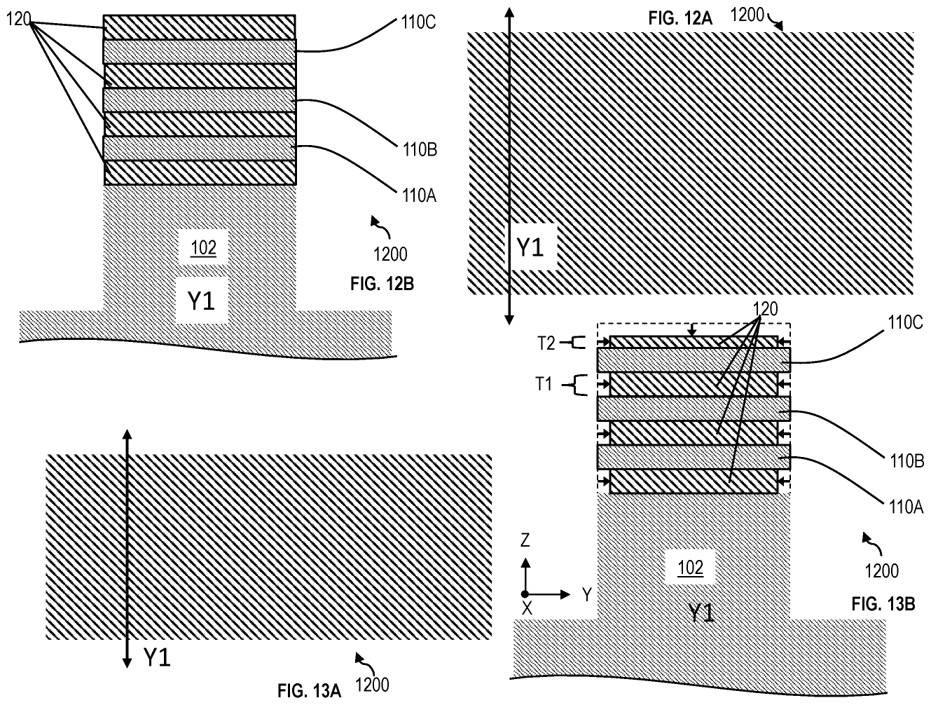

According to one or more embodiments, FIGS. 12-21 depict fabrication operations of a portion of an IC 1200. FIG. 12A depicts a top view of a simplified illustration of a portion of an integrated circuit (IC) 1200, and FIG. 12B depicts a cross-sectional view taken along Y of the IC 1200. For ease of understanding, some layers may be omitted from the various top views so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 1200 as understood by one of ordinary skill in the art. Any suitable lithography processes including deposition techniques and etching techniques can be utilized herein.

FIGS. 12A and 12B depict the IC 1200 having a wafer where several fabrication processes have been performed. FIGS. 12A and 12B illustrate the IC 1200 after nanosheet stack growth, nanosheet patterning, and hard mask strip. A nanosheet stack is formed on a substrate 102. The wafer or substrate 102 may be formed of (pure) silicon. Other suitable materials can be utilized for the substrate 102. As seen in FIG. 12B, a nanosheet stack of semiconductor layers 110A, 110B, and 110C is formed with sacrificial layers 120 formed in between, and a sacrificial layer 120 is formed on top of the top-most semiconductor layer 110C. The semiconductor layers 110A, 110B, and 110C can generally be referred to as semiconductor layers 110 and may include substantially pure silicon. The semiconductor layers 110 will become the channel regions for the nanosheet FET device. The semiconductor layers 110 are nanosheets. Nanosheets can have a thickness of, for example, 5 nanometers. The thickness of a nanosheet can range from about 2-10 nm, and other ranges are possible. The sacrificial layers 120 are formed of silicon germanium (SiGe), where germanium has an atomic percent (%) of about 25% and silicon is the remainder. In one or more embodiments, the atomic percent of germanium can range from about 15-30% while silicon is the remainder in the sacrificial layer 120.

FIGS. 13A and 13B depict the IC 1200 after selective silicon germanium indentation using isotropic etching. Initially, the sacrificial layers 120 have an original thickness T1 in the z-axis. Isotropic etching is performed to etch the ends of the sacrificial layers 120 and reduce the thickness of the top-most sacrificial layer 120, as illustrated by arrows. The top-most sacrificial layer 120 has a reduced thickness T2, where the reduced thickness T2 is less than the original thickness T1.

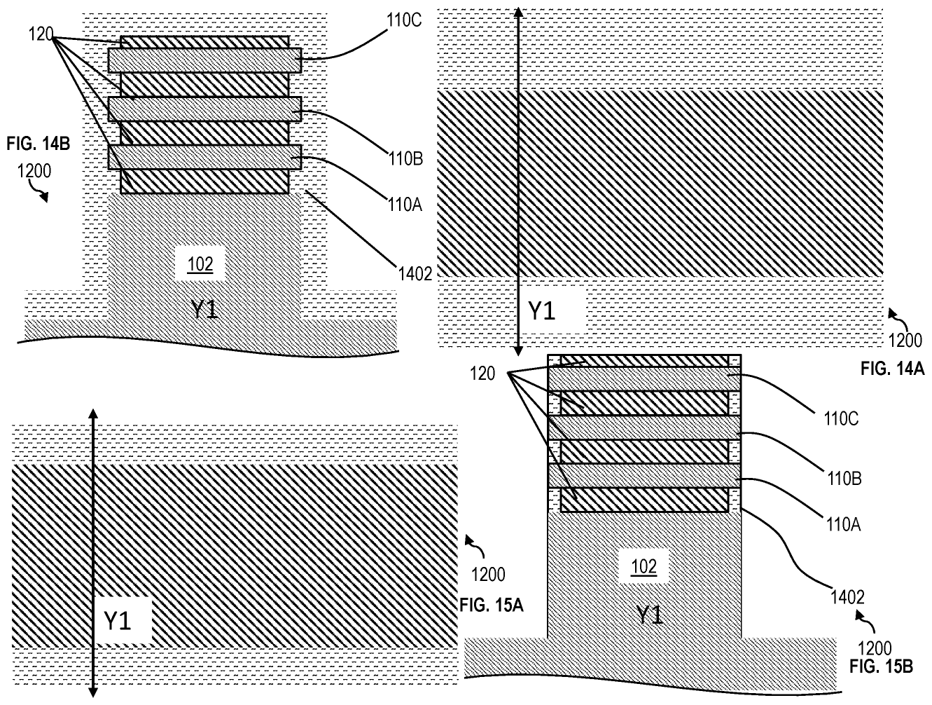

FIGS. 14A and 14B depict the IC 1200 after conformal deposition of silicon germanium material having a high percentage of germanium. A sacrificial layer 1402 is conformally deposited on the IC 1200. The sacrificial layer 1402 includes amorphous silicon germanium, where the atomic percent of germanium can be 35-60% while silicon is the remainder. For example, if the atomic percent of germanium is 35% then the atomic percent of amorphous silicon is 65%. Also, in one or more embodiments, the atomic percent of germanium in the sacrificial layer 1402 increases with a higher atomic percent of germanium in the sacrificial layer 120, thereby maintaining a good etch selectivity between the sacrificial layer 120 and 1402.

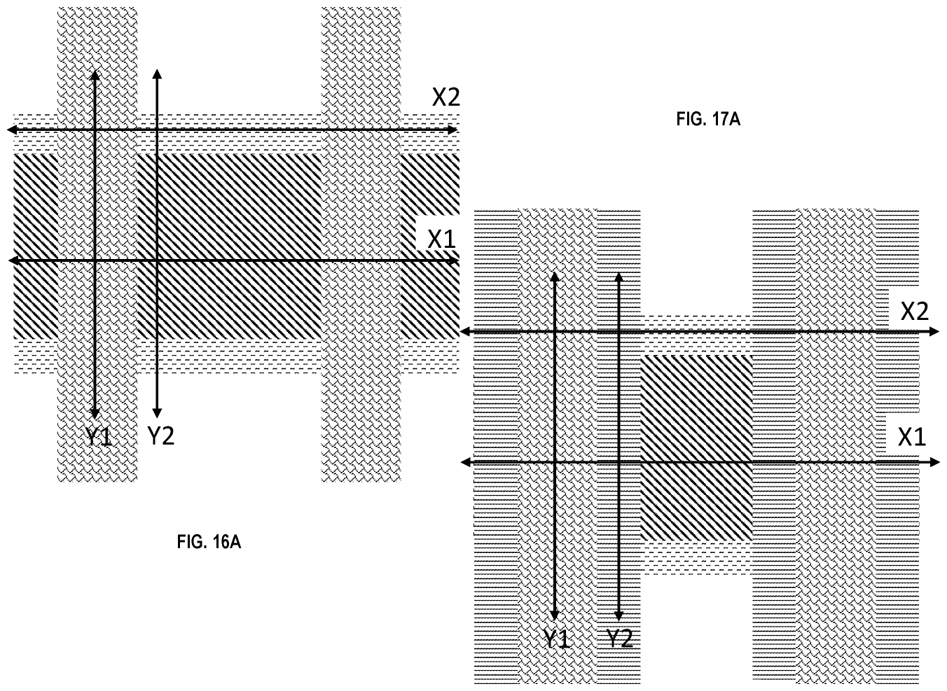

FIGS. 15A and 15B depict the IC 1200 after isotropic etch back of the sacrificial layer 1402. The isotropic etching removes portions of the sacrificial layer 1402 that were not under the semiconductor layers 110. Also, the sacrificial layer 1402 is removed from the top surface of the top-most sacrificial layer 120 while remaining on the sides.

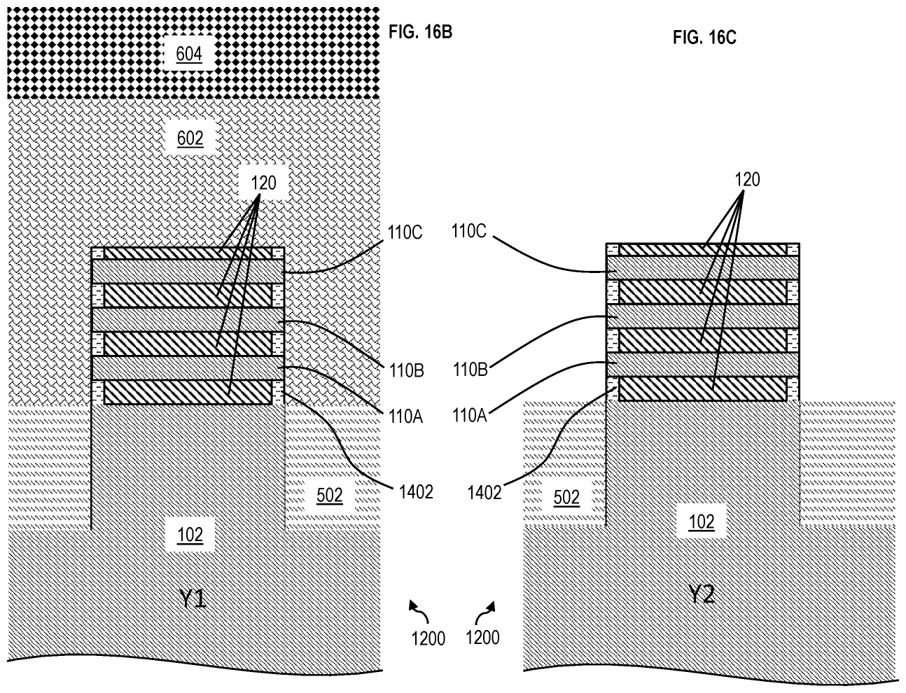

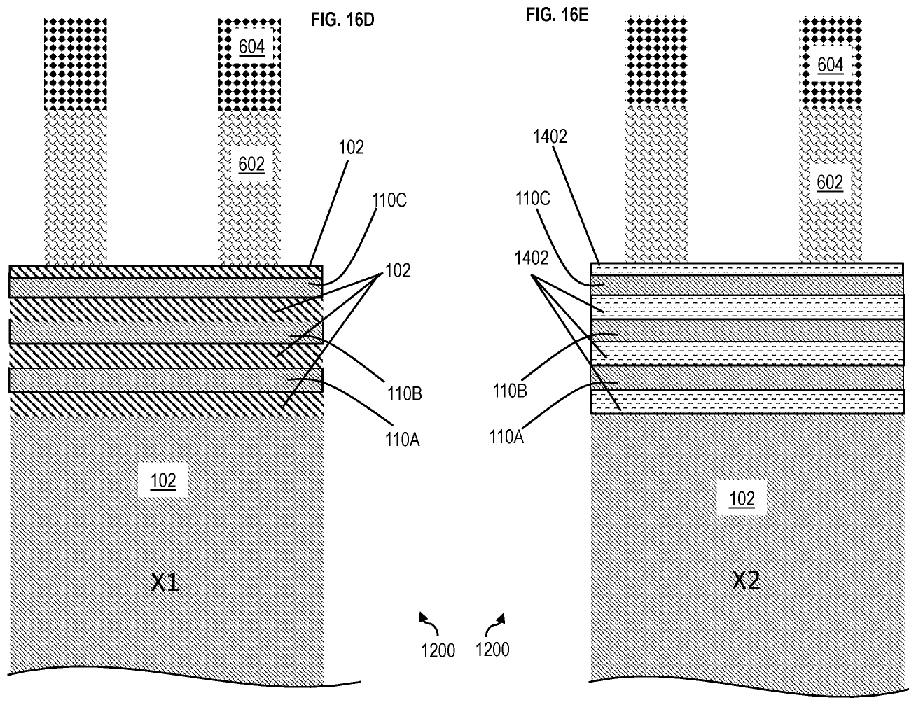

FIGS. 16A, 16B, 16C, 16D, and 16E depict the IC 1200 after dummy gate formation and patterning. FIG. 16A is a top view of a simplified illustration of a portion of the IC 1200. FIG. 16B depicts a cross-sectional view taken along Y1 of the IC 1200, while FIG. 16C depicts a cross-sectional view taken along Y2. FIG. 16D depicts a cross-sectional view taken along X1 of the IC 1200, while FIG. 16D depicts a cross-sectional view taken along X2. The fabrication of FIGS. 16A, 16B, 16C, 16D, and 16E continues from FIGS. 15A and 15B.

As discussed herein, shallow trench isolation formation is performed. Material for the shallow trench isolation (STI) regions 502 is deposited, and etching is performed to etch back the material of the STI regions 502, thereby revealing the fin. Sacrificial gate material is formed on the IC 1200 to be a dummy gate 602, and a hard mask layer 604 is formed on top of the sacrificial gate material. The hard mask layer 604 is patterned, and the patterned hard mask layer 604 is utilized to etch the sacrificial gate material into the dummy gate 602. Example materials of the dummy gate 602 can include amorphous silicon, polycrystalline silicon, etc. Example materials of the hard mask layer 604 can include nitride materials such as silicon nitride.

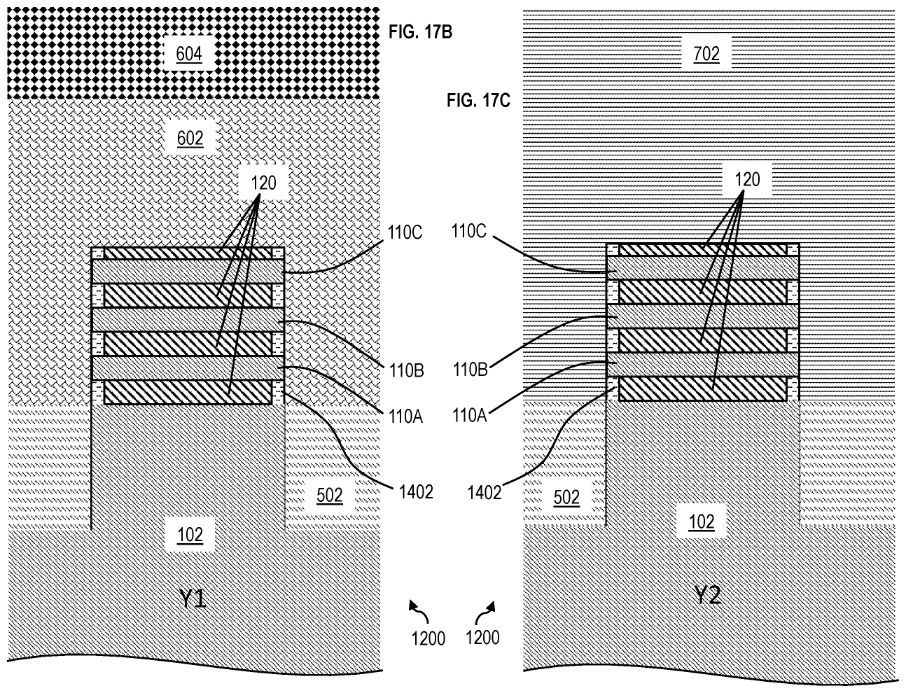

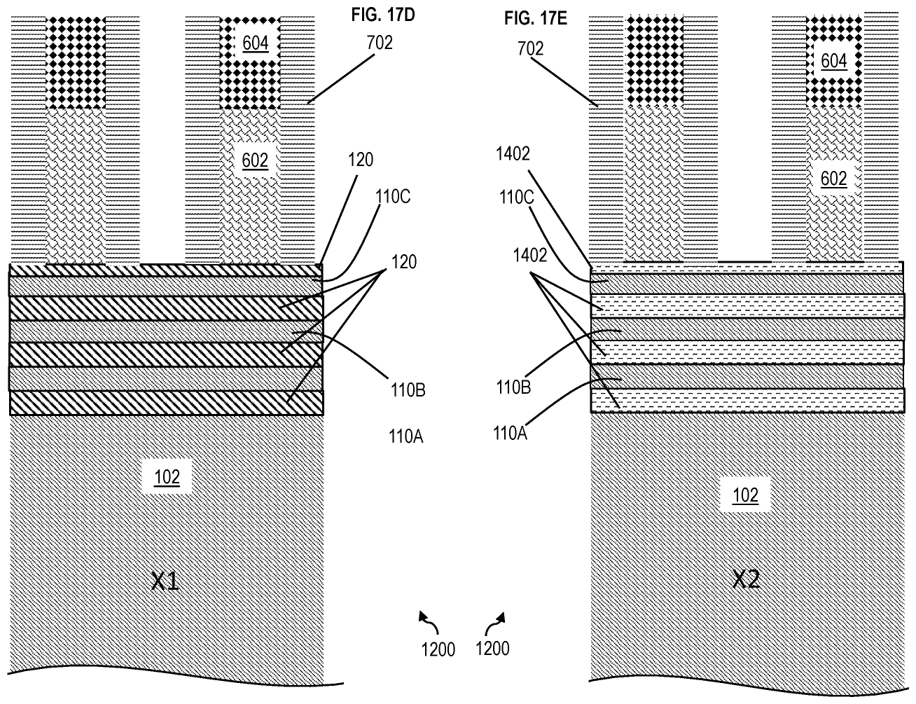

FIGS. 17A, 17B, 17C, 17D, and 17E depict the IC 1200 after gate spacer deposition and etching. Gate spacer material is deposited and etched to form gate spacers 702. Example materials of the gate spacer 702 can include nitride materials, such as SiN, SiBCN, SiOCN, SiOC, etc.

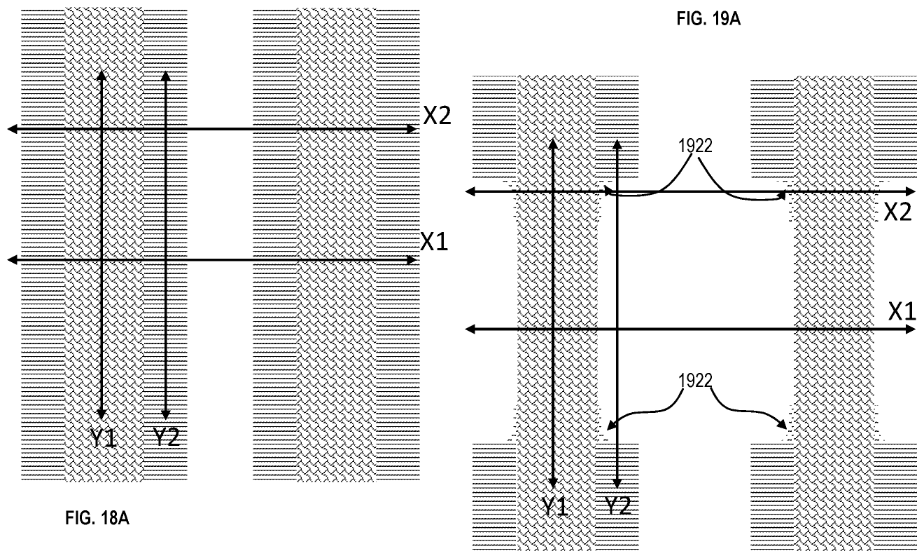

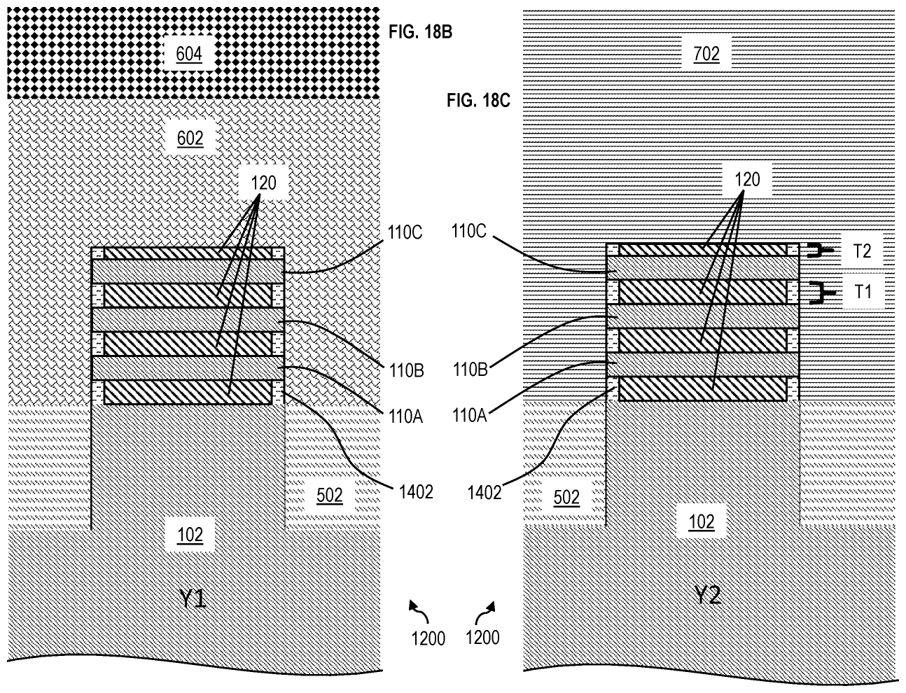

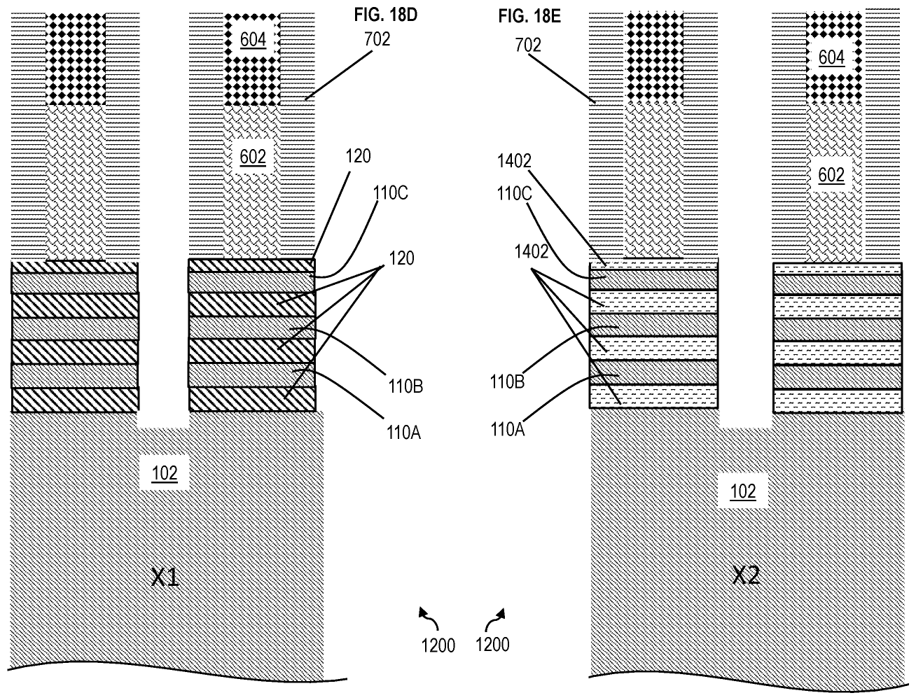

FIGS. 18A, 18B, 18C, 18D, and 18E depict the IC 1200 after fin recess. Directional etching is performed while using the hard mask layer 604 and the gate spacers 702 as a protective mask, in order to trim the nanosheet stack. As a result of the etching, the unprotected portions of the semiconductor layers 110, the sacrificial layers 120, and the sacrificial layers 1402 are removed. Etching continues into a portion of the substrate 102.

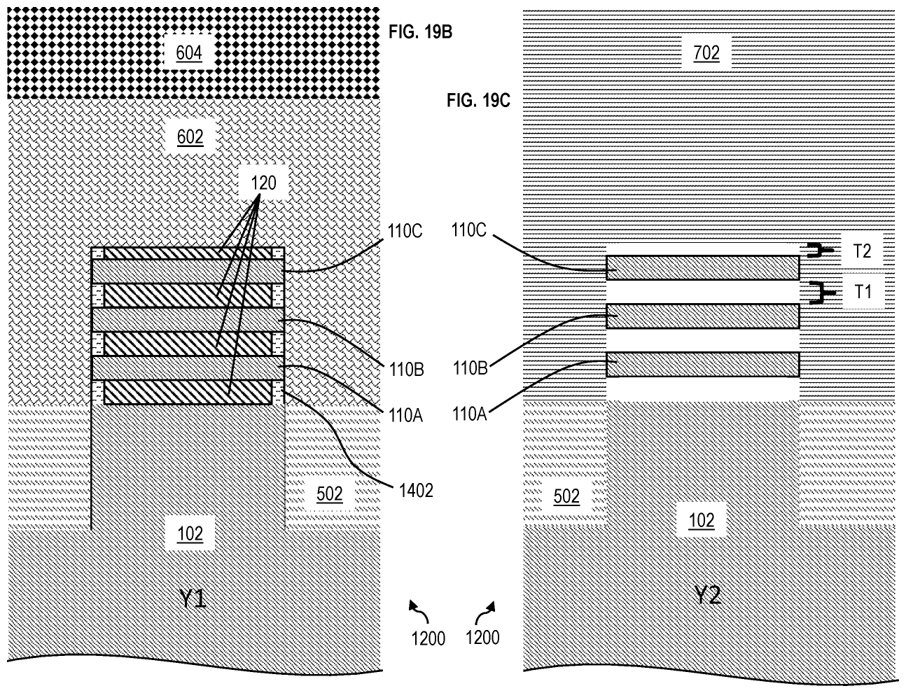

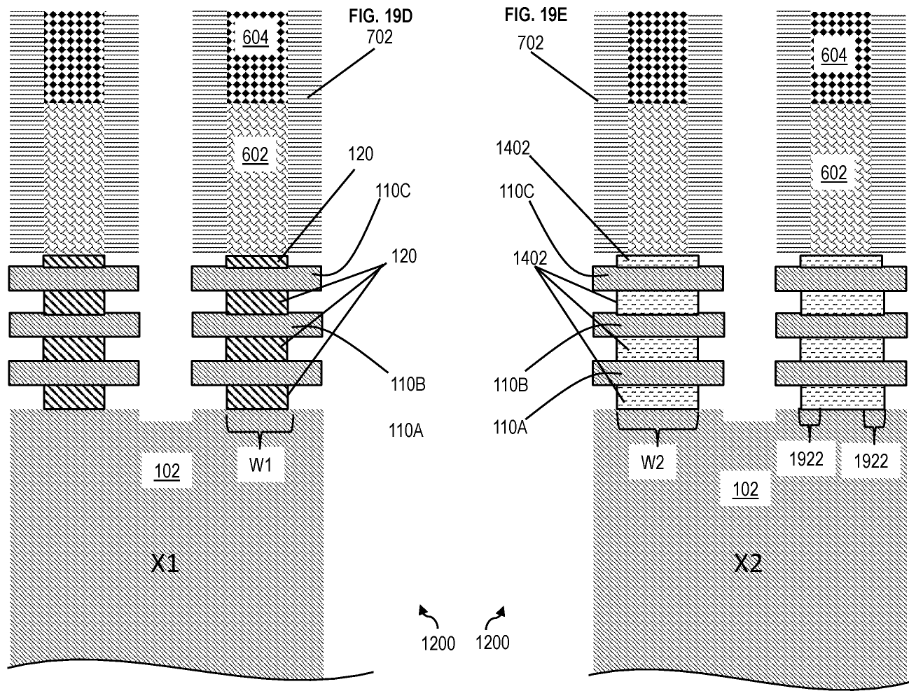

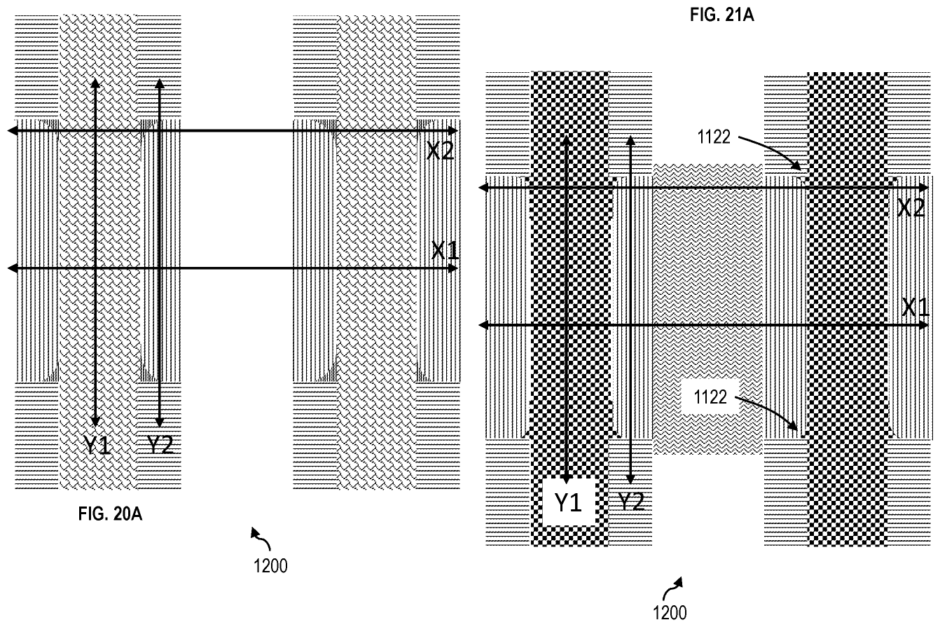

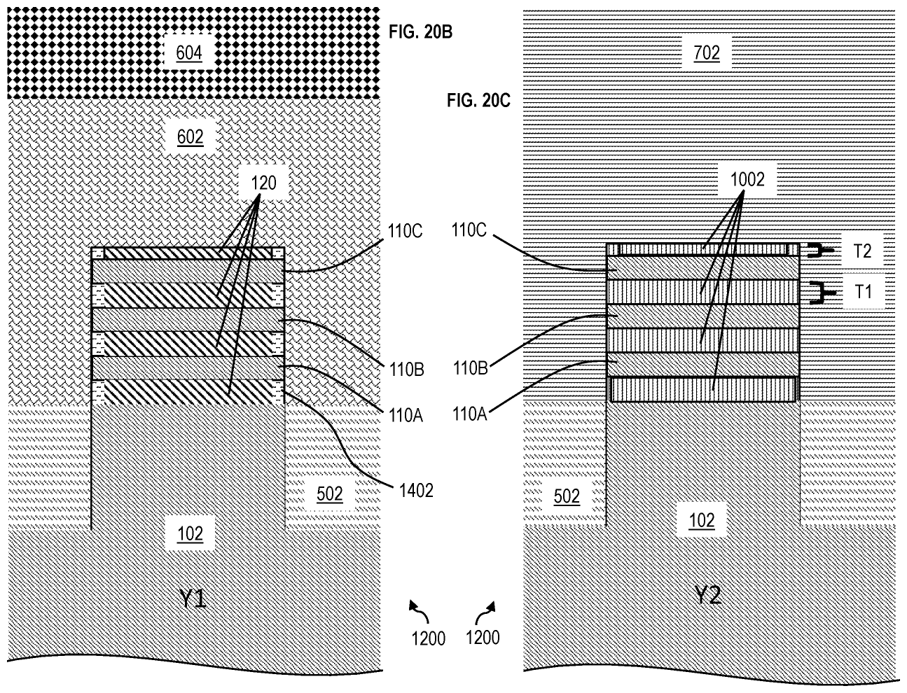

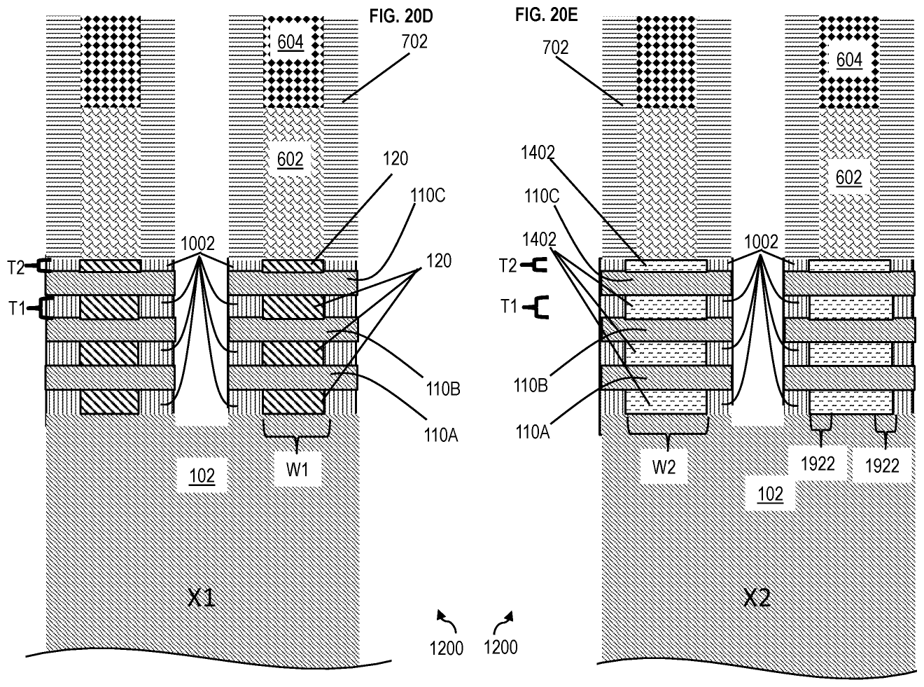

FIGS. 19A, 19B, 19C, 19D, and 19E depict the IC 1200 after inner spacer indentation. In preparation to form inner spacers 1002 (depicted in FIGS. 20A, 20B, 20C, 20D, and 20E), isotropic etching is performed to selectively remove end portions of the sacrificial layers 120 and 1402 resulting in cavities at the ends. Etching is performed that results in a width W1 for the sacrificial layers 120 in the x-axis as depicted in FIG. 19D, and a width W2 for sacrificial layers 1402 in the x-axis as depicted in FIG. 19E. The width W2 is greater than the width W1. The width W2 of sacrificial layers 1402 includes additional portions 1922. The higher germanium percentage in the SiGe material of the sacrificial layers 1402 as compared to the lower germanium percentage in the SiGe material of the sacrificial layers 120 causes the sacrificial layers 1402 to have a faster etch rate than the sacrificial layers 120. The faster etch rate causes the formation of a corner edge depicted as portions 1922 that have a curvature as depicted in FIG. 19A. The curvature of the corner edge portions 1922 of the sacrificial layers 1402 results in an improved inner spacer profile in the y-axis. As noted herein, one or more upper layers may not be illustrated in the top view in order to avoid obscuring the figure and to highlight certain aspects for the reader, according to one or more embodiments.

FIGS. 20A, 20B, 20C, 20D, and 20E depict the IC 1200 after inner spacer formation. Inner spacer material is deposited to fill the cavities, and etching is performed to remove the excess spacer material, resulting in the inner spacers 1002 on the ends of the sacrificial layers 120 and 1402. Example materials of the inner spacers 1002 can include nitrides, low-k dielectric materials, etc. Example materials of the inner spacers 1002 may include SiBCN, SiOCN, SiN, SiOC, SiC, etc. As depicted in FIG. 20C, the top-most inner spacer has the reduced thickness T2, while the other inner spacers have the original thickness T1. As recalled in FIGS. 13A and 13B, isotropic etching was performed to reduce the thickness of the top-most sacrificial layer 120 from the original thickness T1 to the reduced thickness T2, thereby resulting in the subsequent formation of the top-most inner spacer 1002 with the reduced thickness T2 in FIG. 20C. In one or more embodiments, the reduced thickness T1 can be less than half the thickness T2 of the inner spacers. In one or more embodiments, the reduced thickness T1 can be about 50% or less than, but greater than 1% of, the thickness T2. In one or more embodiments, the reduced thickness T1 can be about 40-70% less than the thickness T2.

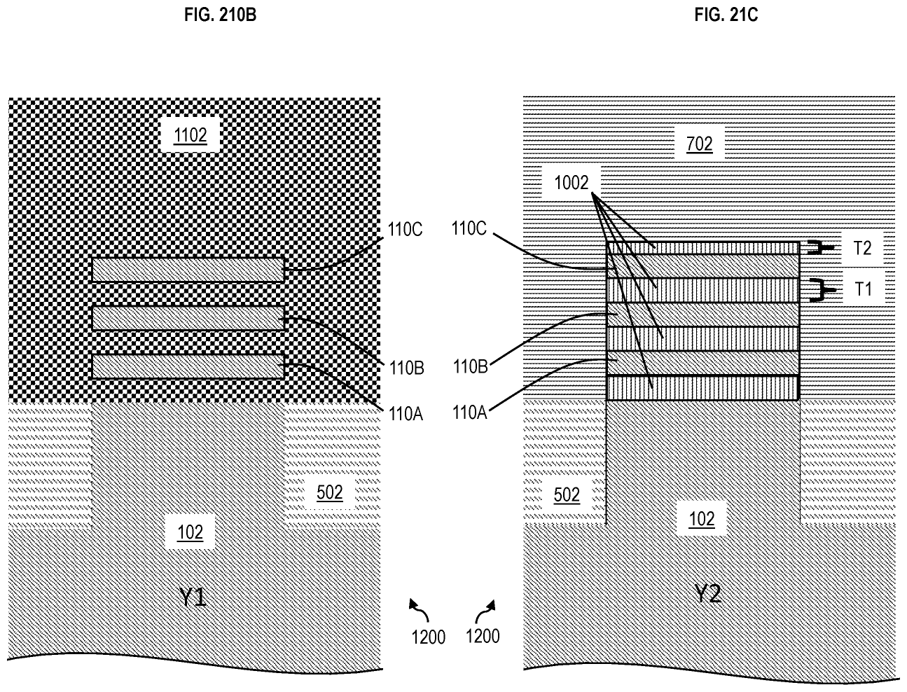

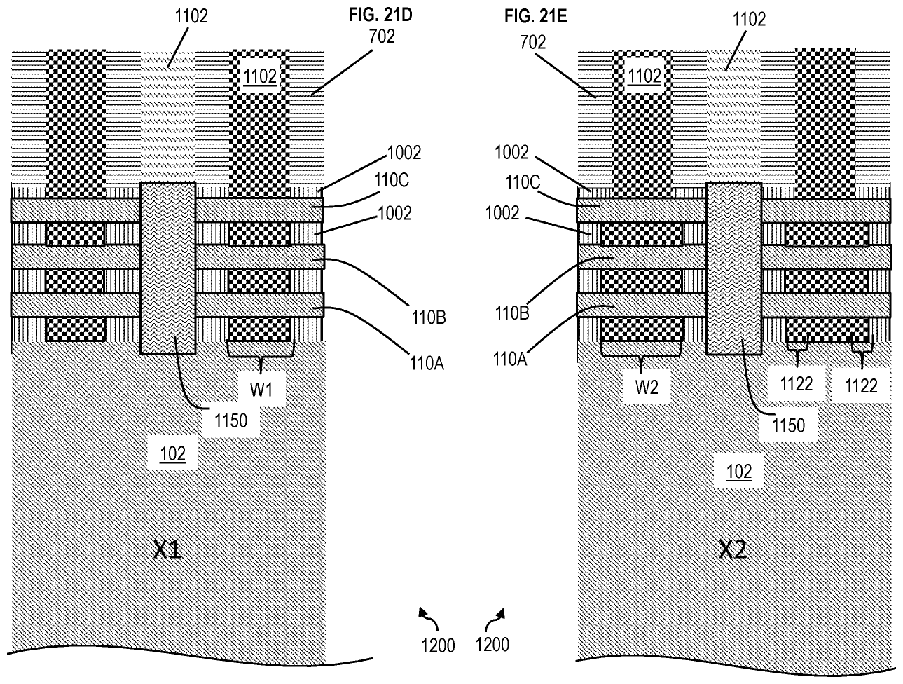

FIGS. 21A, 21B, 21C, 21D, and 21E depict the IC 1200 after source and drain epitaxial deposition, interlayer/intralayer dielectric formation, and replacement gate (RMG) formation. To form epitaxial source/drain regions 1150, semiconductor material is deposited and epitaxially grown from the nanosheet semiconductor layers 110 and the substrate 102. The deposited semiconductor material can be doped with n-type or p-type dopants according to whether an n-type or p-type transistor is being formed.

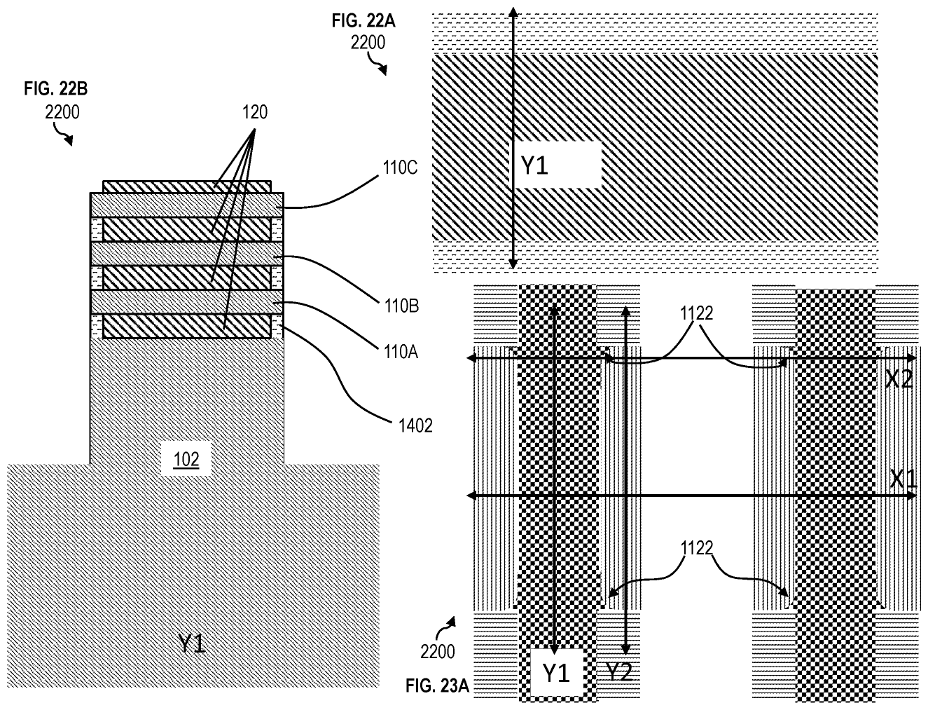

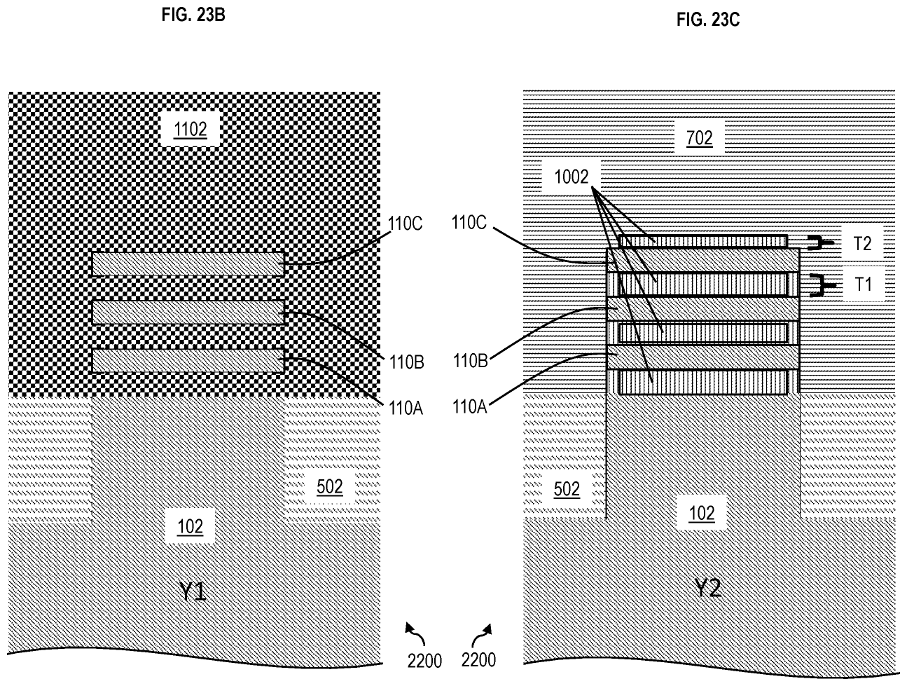

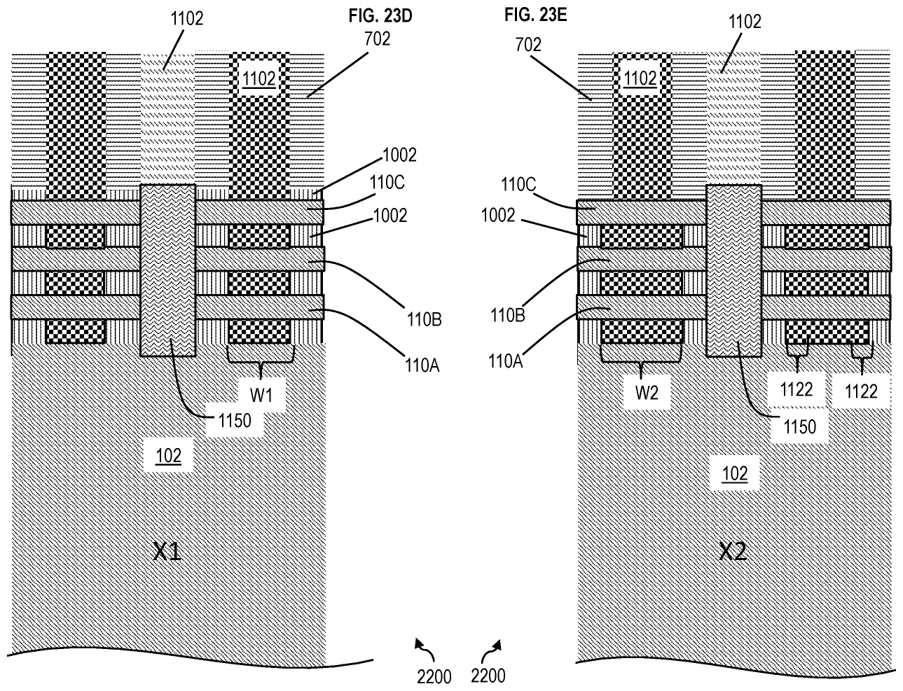

FIGS. 22 and 23 depict a modification to the fabrication operations discussed in FIGS. 12-21. Some of the fabrication operations are omitted.

FIGS. 22A and 22B depict a portion of IC 2200 after fabrication operations analogous to FIGS. 15A and 15B. Unlike FIGS. 15A and 15B, FIGS. 22A and 22B illustrate the IC 2200 after further etching is performed to remove the sacrificial layer 1402 on the side surfaces and top surface of the top-most sacrificial layer 120.

FIGS. 23A, 23B, 23C, 23D, and 23E depict a portion of the IC 2200 after various fabrication operations analogous to FIGS. 16-21. A seen in FIG. 23E, the gate spacers 702 sit directly on the top-most semiconductor layer 110C because of the etching performed to remove the sacrificial layer 1402 on the side surfaces of the top-most sacrificial layer 120 in FIGS. 22A and 22B, thereby exposing the semiconductor layer 110C.

In accordance with one or more embodiments, a method of forming a semiconductor structure (e.g., ICs 100 and 2200) is provided. The method includes providing nanosheets (e.g., semiconductor layers 110) separated by inner spacers 1002, the inner spacers 1002 having a curved portion (e.g., curved spacer corner edge portions 1022) in a dimension. The method includes forming source/drain regions 1150 adjacent to the nanosheets (e.g., semiconductor layers 110) and forming gate material 1102 on the nanosheets (e.g., semiconductor layers 110).

According to one or more embodiments, the curved portion (e.g., curved spacer corner edge portions 1022) of the inner spacers 1002 is adjacent to the gate material 1102. The gate material 1102 is formed with a curved corner edge (e.g., gate corner edge portions 1122). A curved corner edge (e.g., gate corner edge portions 1122) of the gate material 1102 includes a complementary curvature to the curved portion (e.g., curved spacer corner edge portions 1022) of the inner spacers 1002. The inner spacers 1002 include a top-most inner spacer 1002 having a first thickness (e.g., reduced thickness T2) and other inner spacers having a second thickness (e.g., original thickness T1), the first thickness being less than the second thickness (e.g., T2<T1). The top-most inner spacer 1002 is adjacent to a top-most nanosheet (e.g., semiconductor layer 110C) of the nanosheets and gate spacer material, the gate spacer material 702 being formed adjacent to the gate material 1102. The top-most inner spacer 1002 has a first length in the dimension (e.g., the y-axis) less that a second length of the other inner spacers 1002 in the dimension, for example, as depicted in FIGS. 22B and 23C.

The ILD material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
nanosheets separated by inner spacers, the inner spacers having a curved portion in a dimension;
source/drain regions formed adjacent to the nanosheets; and
gate material formed on the nanosheets.

2. The semiconductor structure of claim 1, wherein the curved portion of the inner spacers is adjacent to the gate material.

3. The semiconductor structure of claim 1, wherein the gate material is formed with a curved corner edge.

4. The semiconductor structure of claim 1, wherein a curved corner edge of the gate material comprises a complementary curvature to the curved portion of the inner spacers.

5. The semiconductor structure of claim 1, wherein:
the inner spacers comprise a top-most inner spacer having a first thickness and other inner spacers having a second thickness, the first thickness being less than the second thickness;
the top-most inner spacer is adjacent to a top-most nanosheet of the nanosheets and gate spacer material, the gate spacer material being formed adjacent to the gate material; and
the top-most inner spacer comprises a first length in the dimension less that a second length of the other inner spacers in the dimension.

6. The semiconductor structure of claim 1, wherein a stair-shaped portion of a substrate is formed below the source/drain regions and the gate material.

7. The semiconductor structure of claim 6, wherein a sidewall spacer of silicon germanium material is on the stair-shaped portion.

8. A method comprising:
providing nanosheets separated by inner spacers, the inner spacers having a curved portion in a dimension;
forming source/drain regions adjacent to the nanosheets; and
forming gate material on the nanosheets.

9. The method of claim 8, wherein the curved portion of the inner spacers is adjacent to the gate material.

10. The method of claim 8, wherein the gate material is formed with a curved corner edge.

11. The method of claim 8, wherein a curved corner edge of the gate material comprises a complementary curvature to the curved portion of the inner spacers.

12. The method of claim 8, wherein the inner spacers comprise a top-most inner spacer having a first thickness and other inner spacers having a second thickness, the first thickness being less than the second thickness.

13. The method of claim 12, wherein the top-most inner spacer is adjacent to a top-most nanosheet of the nanosheets and gate spacer material, the gate spacer material being formed adjacent to the gate material.

14. The method of claim 12, wherein the top-most inner spacer comprises a first length in the dimension less that a second length of the other inner spacers in the dimension.

15. A transistor comprising:
nanosheets separated by inner spacers, the inner spacers having a curved portion in a dimension;
gate spacer material formed adjacent to the nanosheets and the inner spacers;
source/drain regions formed adjacent to the nanosheets; and
gate material formed on the nanosheets.

16. The transistor of claim 15, wherein a stair-shaped portion of a substrate is formed below the source/drain regions and the gate material.

17. The transistor of claim 16, wherein a sidewall spacer of silicon germanium material is on the stair-shaped portion.

18. The transistor of claim 15, wherein a curved corner edge of the gate material comprises a complementary curvature to the curved portion of the inner spacers.

19. The transistor of claim 15, wherein the inner spacers comprise a top-most inner spacer having a first thickness and other inner spacers having a second thickness, the first thickness being less than the second thickness.

20. The transistor of claim 19, wherein the top-most inner spacer is adjacent to a top-most nanosheet of the nanosheets.
